(19) United States
(12) Patent Application Publication
(10) Pub. No.: US 2021/0335828 A1
(43) Pub. Date: Oct. 28, 2021

(54) DISPLAY PANEL

(71) Applicant: SHENZHEN CHINA STAR OPTOELECTRONICS SEMICONDUCTOR DISPLAY TECHNOLOGY CO., LTD., Shenzhen (CN)

(72) Inventor: Jiangchuan Chen, Shenzhen (CN)

(21) Appl. No.: 16/624,922

(22) PCT Filed: Nov. 11, 2019
(86) PCT No.: PCT/CN2019/117151

§ 371 Date: Dec. 20, 2019

(30) Foreign Application Priority Data
Sep. 4, 2019 (CN) 201910830786.2

(51) Int. Cl. H01L 27/12; H01L 29/423

(52) U.S. Cl. CPC H01L 27/124; H01L 29/78633; H01L 29/42384

(57) ABSTRACT

A display panel is provided. The display panel includes a base substrate, an active layer, a gate layer, and a threshold voltage adjustment metal layer. The threshold voltage adjustment metal layer is disposed on a side of the active layer away from the gate layer and is connected to the gate layer. When the threshold voltage adjustment metal layer is at a positive potential, a threshold voltage of a switching thin-film transistor is reduced, thereby easily turning on the switching thin-film transistor. When the threshold voltage adjustment metal layer is at a negative potential, the threshold voltage of the switching thin-film transistor is increased, thereby difficultly turning off the switching thin-film transistor. Therefore, a technical problem about high power consumption in the display panels existing in the prior art is solved.

### FIELD OF INVENTION

The present disclosure relates to the field of display technology, and in particular, to a display panel.

### BACKGROUND OF INVENTION

Currently, for most of products, switching thin-film transistors are turned on by a high potential written by a scanning signal terminal, and then pixels are charged by writing a data signal potential. In order to ensure that the signal is completely written, the potential of the scanning signal terminal is necessary to be greatly high. Therefore, there is a problem about power consumption and short usage times of mobile devices.

Therefore, the technical problem about the high power consumption in the display panels existing in the prior art needs be improved.

### SUMMARY OF INVENTION

The present disclosure provides a threshold voltage adjustment circuit and a display panel, thereby enabling to adjust a threshold voltage of a switching thin-film transistor to solve a technical problem about high power consumption existing in conventional display panels.

In order to solve the above-mentioned problem, technical solutions provided by the present disclosure as follows:

The present disclosure provides a display panel, and the display panel is characterized by including:

a base substrate;

an active layer;

a gate layer; and

a threshold voltage adjustment metal layer disposed on a side of the active layer away from the gate layer and connected to the gate layer.

In the display panel provided by the present disclosure, the display panel includes the base substrate, the threshold voltage adjustment metal layer, the active layer, and the gate layer which are disposed in sequence.

In the display panel provided by the present disclosure, the threshold voltage adjustment metal layer is an added film layer.

In the display panel provided by the present disclosure, the threshold voltage adjustment metal layer and a shielding layer are disposed in the same layer.

In the display panel provided by the present disclosure, material of the threshold voltage adjustment metal layer is the same as material of the shielding layer.

In the display panel provided by the present disclosure, in a sub-pixel, one of the threshold voltage adjustment metal layer is disposed to correspond to the active layers of two thin-film transistors.

In the display panel provided by the present disclosure, in a pixel or between adjacent pixels, one of the threshold voltage adjustment metal layer is disposed to correspond to the active layers of a plurality of thin-film transistors.

In the display panel provided by the present disclosure, the display panel includes a source-drain layer, and both of the threshold voltage adjustment metal layer and the gate layer are connected to the source-drain layer.

In the display panel provided by the present disclosure, the threshold voltage adjustment metal layer is directly connected to the gate layer by through-holes.

In the display panel provided by the present disclosure, the display panel includes the base substrate, the gate layer, the active layer, and the threshold voltage adjustment metal layer which are disposed in sequence.

In the display panel provided by the present disclosure, the threshold voltage adjustment metal layer is an added film layer.

In the display panel provided by the present disclosure, the threshold voltage adjustment metal layer and a source-drain layer are disposed in the same layer.

In the display panel provided by the present disclosure, material of the threshold voltage adjustment metal layer is the same as material of the source-drain layer.

In the display panel provided by the present disclosure, the threshold voltage adjustment metal layer and a second metal layer are disposed in the same layer.

In the display panel provided by the present disclosure, material of the threshold voltage adjustment metal layer is the same as material of the second metal layer.

In the display panel provided by the present disclosure, a part of the threshold voltage adjustment metal layer and a source-drain layer are disposed in the same layer, and another part of the threshold voltage adjustment metal layer and a second metal layer are disposed in the same layer in a sub-pixel.

In the display panel provided by the present disclosure, in a sub-pixel, one of the threshold voltage adjustment metal layer is disposed to correspond to the active layers of two thin-film transistors.

In the display panel provided by the present disclosure, in a pixel or between adjacent pixels, one of the threshold voltage adjustment metal layer is disposed to correspond to the active layers of a plurality of thin-film transistors.

In the display panel provided by the present disclosure, the display panel includes a source-drain layer, and both of the threshold voltage adjustment metal layer and the gate layer are connected to the source-drain layer.

In the display panel provided by the present disclosure, the threshold voltage adjustment metal layer is directly connected to the gate layer by through-holes.

Advantageous effects of the present disclosure:

A display panel is provided. The display panel includes the base substrate, the active layer, the gate layer, and the threshold voltage adjustment metal layer. The threshold voltage adjustment metal layer is disposed on the side of the active layer away from the gate layer and is connected to the gate layer. When the threshold voltage adjustment metal layer is at a positive potential, a threshold voltage of a switching thin-film transistor is reduced, thereby easily turning on the switching thin-film transistor. When the threshold voltage adjustment metal layer is at a negative potential, the threshold voltage of the switching thin-film transistor is increased, thereby difficultly turning off the switching thin-film transistor. Therefore, the technical problem about the high power consumption in the display panels existing in the prior art is solved.

### DESCRIPTION OF DRAWINGS

In order to clearly illustrate technical solutions in embodiments of the present disclosure, the drawings required for using in the description of the embodiments is briefly described below. Obviously, the drawings in the following description are only some of the embodiments of the present disclosure. For those skilled in the art, other drawings may also be obtained in accordance with these drawings without making for creative efforts.

FIG. 1 is a first structural schematic view of a top gate of a display panel provided by embodiments of the present disclosure.

FIG. 2 is a second structural schematic view of a top gate of a display panel provided by embodiments of the present disclosure.

FIG. 3 is a structural schematic view of a bottom gate of a display panel provided by embodiments of the present disclosure.

FIG. 4 is a first structural schematic view of a threshold voltage adjustment circuit provided by embodiments of the present disclosure.

FIG. 5 is a first structural schematic view of a pixel driving circuit provided by embodiments of the present disclosure.

FIG. 6 is a second structural schematic view of a pixel driving circuit provided by embodiments of the present disclosure.

### DETAILED DESCRIPTION OF PREFERRED EMBODIMENTS

The following description of various embodiments refers to accompanying drawings to exemplify particular embodiments which can be implemented by the present disclosure. Directional terms mentioned by the present disclosure, such as “upper”, “lower”, “front”, “back”, “left”, “right”, “inner”, “outer”, “side”, etc., are only directions by referring to the accompanying drawings. Therefore, the used directional terms are applied to illustrate and understand the present disclosure, but not to limit the present disclosure. In the drawings, units with similar structures are denoted by the same reference numerals.

For a technical problem about high power consumption of display panels existing in the prior art, the embodiments of the present disclosure may solve this problem.

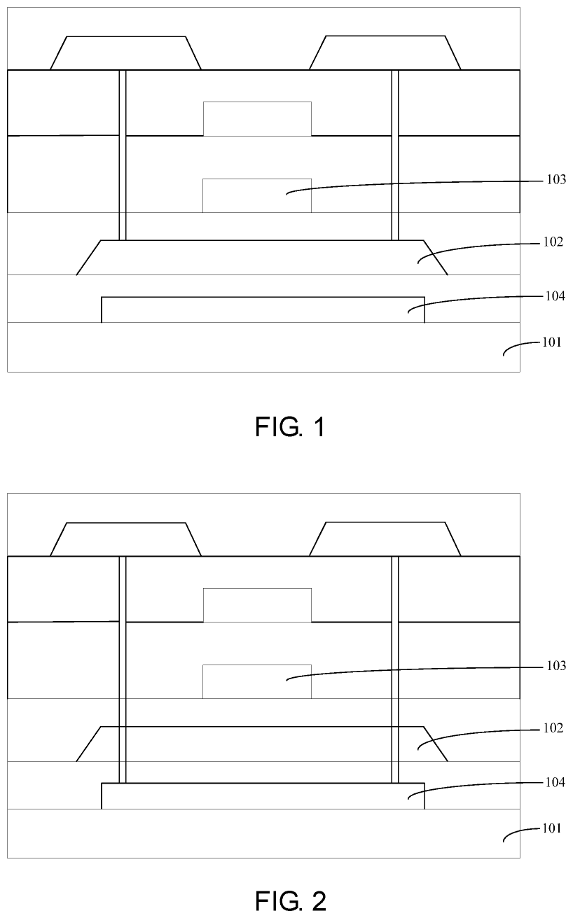

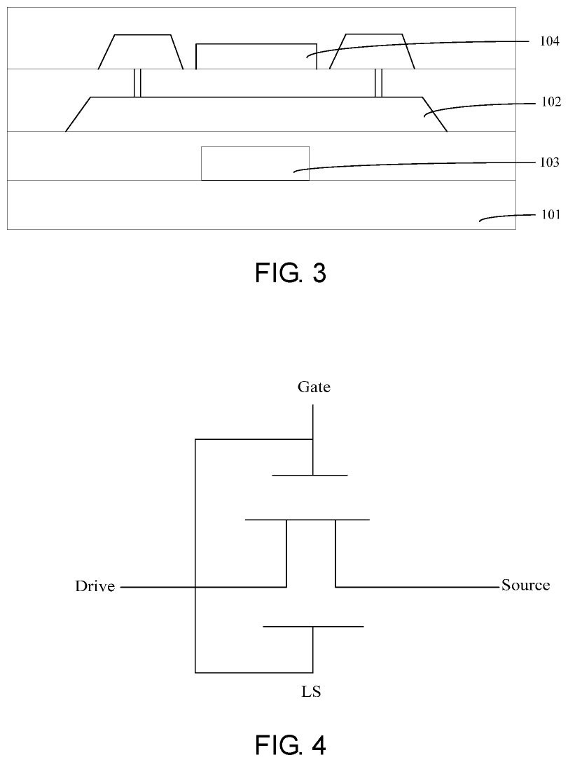

As shown in FIG. 1 and FIG. 3, FIG. 1 is a top-gate structure, and FIG. 3 is a bottom-gate structure. A display panel provided by the present disclosure includes a base substrate 101, an active layer 102, a gate layer 103, and a threshold voltage adjustment metal layer 104. The threshold voltage adjustment metal layer 104 is disposed on a side of the active layer 102 away from the gate layer 103, and the threshold voltage adjustment metal layer 104 is connected to the gate layer 103.

In this embodiment, the display panel includes the base substrate, the active layer, the gate layer, and the threshold voltage adjustment metal layer. The threshold voltage adjustment metal layer is disposed on the side of the active layer away from the gate layer and is connected to the gate layer. When the threshold voltage adjustment metal layer is at a positive potential, a threshold voltage of a switching thin-film transistor is reduced, thereby easily turning on the switching thin-film transistor. When the threshold voltage adjustment metal layer is at a negative potential, the threshold voltage of the switching thin-film transistor is increased, thereby difficultly turning off switching the thin-film transistor. Therefore, the technical problem about the high power consumption in the display panels existing in the prior art is solved.

In an embodiment, as shown in FIG. 1, the display panel includes the base substrate 101, the threshold voltage adjustment metal layer 104, the active layer 102, and the gate layer 103 which are disposed in sequence. In this case, the display panel is in a top-gate configuration, and the threshold voltage adjustment metal layer 104 is disposed on the side of the active layer 102 away from the gate layer 103.

In an embodiment, as shown in FIG. 1, the threshold voltage adjustment metal layer 104 is an added film layer.

In an embodiment, the threshold voltage adjustment metal layer 104 is disposed between the base substrate 101 and a shielding layer.

In an embodiment, the threshold voltage adjustment metal layer 104 is disposed between the shielding layer and the active layer 102.

In an embodiment, as shown in FIG. 1, the threshold voltage adjustment metal layer 104 and the shielding layer are disposed in the same layer.

In an embodiment, material of the threshold voltage adjustment metal layer 104 is the same as material of the shielding layer.

In an embodiment, the material of the threshold voltage adjustment metal layer 104 is different from the material of the shielding layer.

In an embodiment, in a sub-pixel, the threshold voltage adjustment metal layer 104 is disposed to correspond to the active layers 102 of two thin-film transistors.

In an embodiment, in a pixel or between adjacent pixels, the threshold voltage adjustment metal layer 104 is disposed to correspond to the active layers 102 of a plurality of the thin-film transistors.

In an embodiment, the display panel includes a source-drain layer, and both of the threshold voltage adjustment metal layer 104 and the gate layer 103 are connected to the source-drain layer. By conductivity of the source-drain layer, the threshold voltage adjustment metal layer 104 and the gate layer 103 are indirectly connected to be conducted.

In an embodiment, the threshold voltage adjustment metal layer 104 and the gate layer 103 are directly connected by through-holes.

In an embodiment, as shown in FIG. 2, the threshold voltage adjustment metal layer 104 and the gate layer 103 are directly connected by the through-holes, and the gate layer 103 with the top-gate structure is thereabove. During a production process, the gate layer 103 is connected to the threshold voltage adjustment metal layer 104 by the through-holes formed by etching.

In an embodiment, as shown in FIG. 2, the threshold voltage adjustment metal layer 104 and the gate layer 103 are directly connected by the through-holes, and the gate layer 103 with the top-gate structure is thereabove. During a production process, the gate layer 103 is connected to the threshold voltage adjustment metal layer 104 by metal wires through the through-holes.

In an embodiment, as shown in FIG. 2, the threshold voltage adjustment metal layer 104 and the gate layer 103 are directly connected by the through-holes, and the gate layer 103 with the top-gate structure is thereabove. During a production process, the gate layer 103 is connected to the threshold voltage adjustment metal layer 104 by patterning the through-holes.

In an embodiment, as shown in FIG. 3, the display panel includes the base substrate 101, the gate layer 103, the active layer 102, and the threshold voltage adjustment metal layer 104 which are disposed in sequence.

In an embodiment, as shown in FIG. 3, the threshold voltage adjustment metal layer 104 is an added film layer.

In an embodiment, as shown in FIG. 3, the threshold voltage adjustment metal layer 104 and a source-drain layer are disposed in the same layer.

In an embodiment, material of the threshold voltage adjustment metal layer 104 is the same as material of the source-drain layer.

In an embodiment, the threshold voltage adjustment metal layer 104 and a second metal layer are disposed in the same layer.

In an embodiment, the material of the threshold voltage adjustment metal layer 104 is the same as material of the second metal layer.

In an embodiment, in a sub-pixel, a part of the threshold voltage adjustment metal layer 104 and the source-drain layer are disposed in the same layer, and another part of the threshold voltage adjustment metal layer 104 and the second metal layer are disposed in the same layer.

In an embodiment, in a sub-pixel, one of the threshold voltage adjustment metal layer 104 is disposed to correspond to the active layers 102 of two thin-film transistors.

In an embodiment, in a pixel or between adjacent pixels, one of the threshold voltage adjustment metal layer 104 is disposed to correspond to the active layers 102 of a plurality of the thin-film transistors.

In an embodiment, the display panel includes the source-drain layer, and both of the threshold voltage adjustment metal layer 104 and the gate layer 103 are connected to the source-drain layer.

In an embodiment, as shown in FIG. 4, the threshold voltage adjustment metal layer 104 and the gate layer 103 are directly connected by through-holes.

As shown in FIG. 4, the present disclosure further provides a threshold voltage adjustment circuit including a switching thin-film transistor and the threshold voltage adjustment metal layer 104. Gate of the switching thin-film transistor is connected to a first signal, and source/drain is connected to a second signal. The first signal and the second signal jointly control an input voltage of the switching thin-film transistor. The drain/source is connected to a driving thin-film transistor. The threshold voltage adjustment metal layer 104 is disposed on a side of the switching thin-film transistor away from the gate and is equipotentially electrically connected to the gate of the switching thin-film transistor. When the threshold voltage adjustment metal layer 104 is at a positive potential, a threshold voltage of the switching thin-film transistor is reduced, thereby easily turning on the switching thin-film transistor. When the threshold voltage adjustment metal layer 104 is at a negative potential, the threshold voltage of the switching thin-film transistor is increased, thereby difficultly turning off the switching thin-film transistor.

In the embodiment, the threshold voltage adjustment circuit includes the switching thin-film transistor and the threshold voltage adjustment metal layer 104. The gate of the switching thin-film transistor is connected to the first signal, and the source/drain is connected to the second signal. The first signal and the second signal jointly control the input voltage of the switching thin-film transistor. The drain/source is connected to the driving thin-film transistor. The threshold voltage adjustment metal layer 104 is disposed on the side of the switching thin-film transistor away from the gate and is equipotentially electrically connected to the gate of the switching thin-film transistor. When the threshold voltage adjustment metal layer 104 is at the positive potential, the threshold voltage of the switching thin-film transistor is reduced, thereby easily turning on the switching thin-film transistor. When the threshold voltage adjustment metal layer 104 is at the negative potential, the threshold voltage of the switching thin-film transistor is increased, thereby difficultly turning off the switching thin-film transistor. Therefore, the technical problem about the high power consumption of the display panel existing in the prior art.

In an embodiment, the first signal is a scanning signal, and the second is a data signal. The switching thin-film transistor is used to control a compensation voltage to be written to the driving transistor, and the switching thin-film transistor and the threshold voltage adjustment metal layer 104 jointly constitute a voltage written module 20.

In an embodiment, the switching thin-film transistor is a N-type thin-film transistor. In the voltage-writing phase, the data signal is at a low potential, electrical property of the threshold voltage adjustment circuit is positive, and the threshold voltage is increased; however, the data signal is at a high potential, the electrical property of the threshold voltage adjustment circuit is negative, and the threshold voltage is reduced. The lower the threshold voltage is, the lower the input voltage required for turning on the switching thin-film transistor is. Therefore, the switching thin-film transistor is easy to be turned on. Conversely, the higher the threshold voltage is, the more difficult the switching thin-film transistor is turned on and turned off.

In an embodiment, the switching thin-film transistor is a P-type thin-film transistor. In the voltage-writing phase, the data signal is at a low potential, the electrical property of the threshold voltage adjustment circuit is negative, and the threshold voltage is increased; however, the data signal is at a high potential, the electrical property of the threshold voltage adjustment circuit is positive, and the threshold voltage is reduced. The lower the threshold voltage is, the lower the input voltage required for turning on the switching thin-film transistor is. Therefore, the switching thin-film transistor is easy to be turned on. Conversely, the higher the threshold voltage is, the more difficult the switching thin-film transistor is turned on and turned off.

In an embodiment, the first signal is the scanning signal, and the second signal is a reset signal. In the reset phase, the switching thin-film transistor is used to control a reset voltage to be provided to the driving transistor and light-emitting diodes. The switching thin-film transistor and the threshold voltage adjustment metal layer 104 jointly constitute a reset module 40.

In an embodiment, the switching thin-film transistor is the N-type thin-film transistor. In the reset phase, the reset signal is at a low potential, the electrical property of the threshold voltage adjustment circuit is positive, and the threshold voltage is increased; however, the reset signal is at a high potential, the electrical property of the threshold voltage adjustment circuit is negative, and the threshold voltage is reduced. The lower the threshold voltage is, the lower the input voltage required for turning on the switching thin-film transistor is. Therefore, the switching thin-film transistor is easy to be turned on. Conversely, the higher the threshold voltage is, the more difficult the switching thin-film transistor is turned on and turned off.

In an embodiment, the switching thin-film transistor is the P-type thin-film transistor. In the voltage-writing phase, the reset signal is at a low potential, the electrical property of the threshold voltage adjustment circuit is negative, and the threshold voltage is increased; however, the reset signal is at a high potential, the electrical property of the threshold voltage adjustment circuit is positive, and the threshold voltage is reduced. The lower the threshold voltage is, the lower the input voltage required for turning on the switching thin-film transistor is. Therefore, the switching thin-film transistor is easy to be turned on. Conversely, the higher the threshold voltage is, the more difficult the switching thin-film transistor is turned on and turned off.

Based on the same concept of the disclosure, the embodiments of the present disclosure provide a display panel including: the threshold voltage adjustment circuit provided by any embodiments of the disclosure. The display panel may be: cell phones, tablets, televisions, monitors, laptops, digital photo frames, navigators, and any products or parts with the display function.

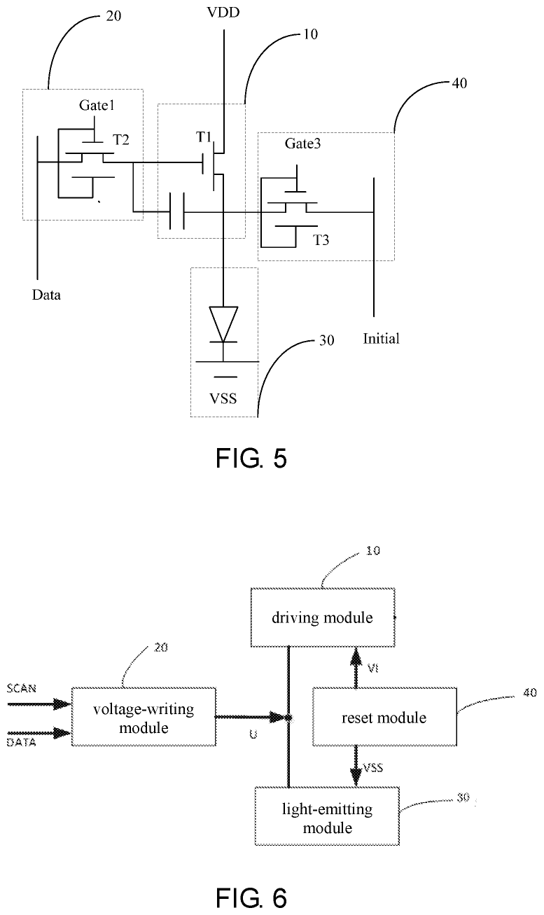

As shown in FIG. 5, the present disclosure provides a pixel driving circuit including a voltage-writing module 20, a driving module 10, a reset module 40, and a light-emitting module 30. The driving module 10 is electrically connected to the light-emitting module 30, and the voltage-writing module 20 is electrically connected to the driving module 10. The voltage-writing module 20 accesses the scanning signal and the data signal. An end of the reset module 40 is connected to the driving module 10 and the light-emitting module 30, and another end of the reset module 40 accesses a reference voltage. The voltage-writing module 20 is used to write a compensation voltage to the driving module 10. The reset module 40 is used for a reset phase of the pixel driving circuit and provides a reset voltage to the driving module 10 and the light-emitting module 30. The driving module 10 is used to control the light-emitting module 30 to emit light in accordance with the reset voltage. Both of the voltage-writing module 20 and the reset module 40 include at least one thin-film transistor, and a side of source and drain of the thin-film transistor is provided with a shielding layer which is used to change electrical properties of the voltage-writing module 20 and the reset module 40 in accordance with the voltage accessed to gate of the thin-film transistor.

FIG. 6 is a structural schematic view of a pixel driving circuit provided by the embodiments of the present disclosure. As shown in FIG. 3, the pixel driving circuit includes the voltage-writing module 20, the driving module 10, the reset module 40, and the light-emitting module 30.

As shown in FIG. 6, the driving module 10 is electrically connected to the light-emitting module 30. An end is electrically connected to the driving module 10, and another end accesses a light-emitting control signal (EM). The voltage-writing module 20 is electrically connected to the driving module 10 and the light-emitting module 30 respectively. The voltage-writing module 20 is provided with ports accessing the scanning signal (SCAN) and the data signal (DATA). Two ends of the reset module 40 are connected to the driving module 10 and the light-emitting module 30.

As shown in FIG. 6, the voltage-writing module 20 is used to write the compensation voltage (U) to the driving module 10. The reset module 40 is used for the reset phase of the pixel driving circuit, provides a predetermined voltage (VI) to the driving module 10, and provides the reset voltage (VSS) to the light-emitting module 30. The driving module 1010 is used to control the light-emitting module 30 to emit the light in accordance with the predetermined voltage (VI). The predetermined voltage (VI) is not equal to the reset voltage (VSS), and both of the predetermined voltage (VI) and the reset voltage (VSS) are not positive values.

In an embodiment, the voltage-writing module 20 includes a second thin-film transistor, and the second thin-film transistor is a switching transistor. Gate of the second thin-film transistor is electrically connected to the shielding layer and accesses the scanning signal, drain accesses the data signal, and source of the second thin-film transistor accesses drain of a first thin-film transistor.

In an embodiment, the reset module 40 includes a third thin-film transistor, and the third thin-film transistor is a reset transistor. Gate of the third thin-film transistor is electrically connected to the shielding layer, source of the third thin-film transistor accesses the driving module 10 and the light-emitting module 30, and drain accesses the reset signal, thereby providing the reset voltage to the driving module 10 and the light-emitting module 30.

In an embodiment, the light-emitting module 30 includes a plurality of light-emitting diodes arranged in parallel. Anodes of the light-emitting diodes access the driving module 10, and cathodes of the light-emitting diodes access negative voltage of a power source.

In an embodiment, the pixel driving circuit is provided with the reset phase, the voltage-writing phase, and a light-emitting phase. When the pixel driving circuit is in the reset phase, the driving module 10 and the reset module 40 are conducted, and the voltage-writing module 20 is disconnected from the light-emitting module 30. When the pixel driving circuit is in the voltage-writing phase, the driving module 10 and the voltage-writing module 20 are conducted, and the reset module 40 is disconnected from the light-emitting module 30. When the pixel driving circuit is in the light-emitting phase, the driving module 10 and the light-emitting module 30 are conducted, and the voltage-writing module 20 is disconnected from the reset module 40.

In an embodiment, the first thin-film transistor, the second thin-film transistor, and the third transistor are the P-type thin-film transistors. In the reset phase, the reset signal is at a low potential, the scanning signal and the data signal are at a high potential, electrical property of the reset module 40 is positive, and electrical property of the voltage-writing module 20 is negative. In the voltage-writing phase, the scanning signal and the data signal are at a low potential, the reset signal is at a high potential, the electrical property of the voltage-writing module 20 is positive, and the electrical property of the reset module 40 is negative. In the light-emitting phase, the scanning signal and the data signal are at a high potential, the reset signal is at a low potential, and the light-emitting module 30 emits the light.

In an embodiment, the first thin-film transistor, the second thin-film transistor, and the third transistor are the N-type thin-film transistors. In the reset phase, the reset signal is at a high potential, the scanning signal and the data signal are at a low potential, the electrical property of the reset module 40 is negative, and the electrical property of the voltage-writing module 20 is positive. In the voltage-writing phase, the scanning signal and the data signal are at a high potential, the reset signal is at a low potential, the electrical property of the voltage-writing module 20 is negative, and the electrical property of the reset module 40 is positive. In the light-emitting phase, the scanning signal and the data signal are at a high potential, the reset signal is at a low potential, and the light-emitting module 30 emits the light.

In an embodiment, the scanning signal, the data signal, and the reset signal are generated by an external timing controller.

The present disclosure further provides a display device including the pixel driving circuit and the timing controller. The timing controller is used to control the scanning signal, the data signal, and the reset signal in the pixel driving circuit.

In an embodiment, in the display device, the driving module 10 includes the first thin-film transistor and a storage capacitor. The first thin-film transistor is a driving transistor, the drain of the first thin-film transistor is connected to positive voltage of the power source, source of the first thin-film transistor is connected to the light-emitting module 30, and gate of the first thin-film transistor is connected to the voltage-writing module 20. An end of the storage capacitor accesses the positive voltage of the power source, and another end of the storage capacitor is connected to the gate of the first thin-film transistor.

In an embodiment, in the display device, the voltage-writing module 20 includes the second thin-film transistor, and the second thin-film transistor is the switching transistor. The gate of the second thin-film transistor is electrically connected to the shielding and accesses the scanning signal, the drain accesses the data signal, and the source of the second thin-film transistor accesses the gate of the first thin-film transistor.

In an embodiment, in the display device, the reset module 40 includes the third thin-film transistor, and the third thin-film transistor is the reset transistor. The gate of the third thin-film transistor is electrically connected to the shielding layer, the source of the third thin-film transistor accesses the driving module 10 and the light-emitting module 30, and the drain of the third thin-film transistor accesses the reset signal, thereby providing the reset voltage to the driving module 10 and the light-emitting module 30.

In an embodiment, in the display device, the light-emitting module includes a plurality of the light-emitting diodes arranged in parallel. The anodes of the light-emitting diodes access the driving module 10, and the cathodes of the light-emitting diodes access the negative voltage of the power source.

In an embodiment, in the display device, the pixel driving circuit is provided with the reset phase, the voltage-writing phase, and a light-emitting phase. When the pixel driving circuit is in the reset phase, the driving module 10 and the reset module 40 are conducted, and the voltage-writing module 20 is disconnected from the light-emitting module 30. When the pixel driving circuit is in the voltage-writing phase, the driving module 10 and the voltage-writing module 20 are conducted, and the reset module 40 is disconnected from the light-emitting module 30. When the pixel driving circuit is in the light-emitting phase, the driving module 10 and the light-emitting module 30 are conducted, and the voltage-writing module 20 is disconnected from the reset module 40.

In an embodiment, in the display device, the first thin-film transistor, the second thin-film transistor, and the third transistor are the P-type thin-film transistors. In the reset phase, the reset signal is at the low potential, the scanning signal and the data signal are at the high potential, the electrical property of the reset module 40 is positive, and the electrical property of the voltage-writing module 20 is negative. In the voltage-writing phase, the scanning signal and the data signal are at the low potential, the reset signal is at the high potential, the electrical property of the voltage-writing module 20 is positive, and the electrical property of the reset module 40 is negative. In the light-emitting phase, the scanning signal and the data signal are at the high potential, the reset signal is at the low potential, and the light-emitting module 30 emits the light.

In an embodiment, in the display device, the first thin-film transistor, the second thin-film transistor, and the third transistor are the N-type thin-film transistors. In the reset phase, the reset signal is at the high potential, the scanning signal and the data signal are at the low potential, the electrical property of the reset module 40 is negative, and the electrical property of the voltage-writing module 20 is positive. In the voltage-writing phase, the scanning signal and the data signal are at the high potential, the reset signal is at the low potential, the electrical property of the voltage-writing module 20 is negative, and the electrical property of the reset module 40 is positive. In the light-emitting phase, the scanning signal and the data signal are at the high potential, the reset signal is at the low potential, and the light-emitting module 30 emits the light.

In an embodiment, in the display device, the scanning signal, the data signal, and the reset signal are generated by the external timing controller.

According to the above embodiments, it can be known that:

The present disclosure provides a display panel. The display panel includes the base substrate, the active layer, the gate layer, and the threshold voltage adjustment metal layer. The threshold voltage adjustment metal layer is disposed on the side of the active layer away from the gate layer and is connected to the gate layer. When the threshold voltage adjustment metal layer is at the positive potential, the threshold voltage of the switching thin-film transistor is reduced, thereby easily turning on the switching thin-film transistor. When the threshold voltage adjustment metal layer is at the negative potential, the threshold voltage of the switching thin-film transistor is increased, thereby difficultly turning off the switching thin-film transistor. Therefore, the technical problem about the high power consumption in the display panels existing in the prior art is solved.

In summary, although the present disclosure has been disclosed with above preferred embodiments, the above preferred embodiments don't intend to limit the present disclosure, and those skilled in the art may make various changes and modifications without departing from the spirit and the scope of the present disclosure. Therefore, the protection scope of the present disclosure is defined by the scope of the claims.

What is claimed is:

1. A display panel, comprising:
a base substrate;
an active layer;
a gate layer; and
a threshold voltage adjustment metal layer disposed on a side of the active layer away from the gate layer and connected to the gate layer.

2. The display panel according to claim 1, wherein the display panel includes the base substrate, the threshold voltage adjustment metal layer, the active layer, and the gate layer which are disposed in sequence.

3. The display panel according to claim 2, wherein the threshold voltage adjustment metal layer is an added film layer.

4. The display panel according to claim 2, wherein the threshold voltage adjustment metal layer and a shielding layer are disposed in the same layer.

5. The display panel according to claim 4, wherein material of the threshold voltage adjustment metal layer is the same as material of the shielding layer.

6. The display panel according to claim 2, wherein in a sub-pixel, one of the threshold voltage adjustment metal layer is disposed to correspond to the active layers of two thin-film transistors.

7. The display panel according to claim 2, wherein in a pixel or between adjacent pixels, one of the threshold voltage adjustment metal layer is disposed to correspond to the active layers of a plurality of thin-film transistors.

8. The display panel according to claim 2, wherein the display panel includes a source-drain layer, and both of the threshold voltage adjustment metal layer and the gate layer are connected to the source-drain layer.

9. The display panel according to claim 2, wherein the threshold voltage adjustment metal layer is directly connected to the gate layer by through-holes.

10. The display panel according to claim 1, wherein the display panel includes the base substrate, the gate layer, the active layer, and the threshold voltage adjustment metal layer which are disposed in sequence.

11. The display panel according to claim 10, wherein the threshold voltage adjustment metal layer is an added film layer.

12. The display panel according to claim 10, wherein the threshold voltage adjustment metal layer and a source-drain layer are disposed in the same layer.

13. The display panel according to claim 12, wherein material of the threshold voltage adjustment metal layer is the same as material of the source-drain layer.

14. The display panel according to claim 10, wherein the threshold voltage adjustment metal layer and a second metal layer are disposed in the same layer.

15. The display panel according to claim 14, wherein material of the threshold voltage adjustment metal layer is the same as material of the second metal layer.

16. The display panel according to claim 10, wherein a part of the threshold voltage adjustment metal layer and a source-drain layer are disposed in the same layer, and another part of the threshold voltage adjustment metal layer and a second metal layer are disposed in the same layer in a sub-pixel.

17. The display panel according to claim 10, wherein in a sub-pixel, one of the threshold voltage adjustment metal layer is disposed to correspond to the active layers of two thin-film transistors.

18. The display panel according to claim 10, wherein in a pixel or between adjacent pixels, one of the threshold voltage adjustment metal layer is disposed to correspond to the active layers of a plurality of thin-film transistors.

19. The display panel according to claim 10, wherein the display panel includes a source-drain layer, and both of the threshold voltage adjustment metal layer and the gate layer are connected to the source-drain layer.

20. The display panel according to claim 10, wherein the threshold voltage adjustment metal layer is directly connected to the gate layer by through-holes.
